(19) United States
(12) Patent Application Publication
(10) Pub. No.: US 2010/0206376 A1
(43) Pub. Date: Aug. 19, 2010

(54) SOLAR CELL, METHOD AND APPARATUS FOR MANUFACTURING SOLAR CELL, AND METHOD OF DEPOSITING THIN FILM LAYER

(76) Inventors: Dongjoo You, Seoul (KR); Sehwon Ahn, Seoul (KR); Heonmin Lee, Seoul (KR); Sunho Kim, Seoul (KR); Jeonghun Son, Seoul (KR)

Correspondence Address: BIRCH STEWART KOLASCH & BIRCH, PO BOX 747, FALLS CHURCH, VA, 22040-0747, US

(21) Appl. No.: 12/705,477

(22) Filed: Feb. 12, 2010

(30) Foreign Application Priority Data
Feb. 16, 2009 (KR) 10-2009-0012494

(51) Int. Cl. H01L 31/04; H01L 31/18; H01L 21/203

(52) U.S. Cl. 136/256; 438/93; 438/680; 118/715; 257/E31.032; 257/E21.091

(57) ABSTRACT

A solar cell, a method and apparatus for manufacturing a solar cell, and a method of depositing a thin film layer are disclosed. The manufacturing apparatus of a solar cell includes a substrate; a first electrode disposed on the substrate; a second electrode; and a photoelectric conversion layer disposed between the first electrode and the second electrode, wherein the photoelectric conversion layer includes a micro-crystalline silicon layer, and sensitivity of the micro-crystalline silicon layer is about 100 to about 1,000, the sensitivity being a ratio expressed as photo conductivity (PC)/dark conductivity (DC).

This application claims priority to Korean Patent Application No. 10-2009-0012494 filed on Feb. 16, 2009, the entire contents of which is incorporated herein by reference for all purposes as if fully set forth herein.

### BACKGROUND OF THE INVENTION

1. Field of the Invention

Embodiments of the invention relate to a solar cell, a method and apparatus for manufacturing a solar cell, and a method of depositing a thin film layer.

2. Discussion of the Related Art

Nowadays, as exhaustion of existing energy resources such as oil and coal is predicted, interest about alternative energy for replacing the existing energy resources increases. A solar cell using solar energy as alternative energy generates electrical energy from solar energy, and because energy resources of the solar energy are abundant and there is no problem of environmental contamination, the solar cell has been in the spotlight.

The solar cell is an element for converting light to electricity and comprises a p-type semiconductor and an n-type semiconductor.

In general, when light is applied from the outside, pairs of electrons and holes are formed within a semiconductor of the solar cell by the applied light, and electrons move to an n-type semiconductor and holes move to a p-type semiconductor by an electric field generated within the semiconductor, thereby generating electric power.

### SUMMARY OF THE INVENTION

In one aspect, there is a solar cell including a substrate, a first electrode disposed on the substrate, a second electrode and a photoelectric conversion layer disposed between the first electrode and the second electrode, wherein the photoelectric conversion layer comprises a micro-crystalline silicon layer, and sensitivity of the micro-crystalline silicon layer is about 100 to about 1,000, the sensitivity being expressed as photo conductivity (PC)/dark conductivity (DC).

The sensitivity of the micro-crystalline silicon layer is about 320 to about 730.

The photoelectric conversion layer includes a p-type semiconductor layer, an n-type semiconductor layer, and an i-type semiconductor layer.

The i-type semiconductor layer is the micro-crystalline silicon layer.

The photoelectric conversion layer further includes a first photoelectric conversion layer including a first p-type semiconductor layer, a first n-type semiconductor layer, and a first i-type semiconductor layer and a second photoelectric conversion layer including a second p-type semiconductor layer, a second n-type semiconductor layer, and a second i-type semiconductor layer.

The first photoelectric conversion layer and the second photoelectric conversion layer are sequentially disposed from a light incidence plane of the solar cell, and the second i-type semiconductor layer is the micro-crystalline silicon layer.

The photoelectric conversion layer further includes a first photoelectric conversion layer including a first p-type semiconductor layer, a first n-type semiconductor layer, and a first i-type semiconductor layer, a second photoelectric conversion layer including a second p-type semiconductor layer, a second n-type semiconductor layer, and a second i-type semiconductor layer and a third photoelectric conversion layer including a third p-type semiconductor layer, a third n-type semiconductor layer, and a third i-type semiconductor layer.

The first photoelectric conversion layer, the second photoelectric conversion layer, and the third photoelectric conversion layer are sequentially disposed from a light incidence plane of the solar cell, and the third i-type semiconductor layer is the micro-crystalline silicon layer.

In another aspect, there is a manufacturing apparatus of a solar cell, the manufacturing apparatus including a chamber, a dispersion portion configured to disperse gas injected into the chamber, a second distribution plate configured to distribute the gas supplied from the dispersion portion and a first distribution plate configured to redistribute the gas that passes through the second distribution plate.

The dispersion portion has a plate shape.

The first distribution plate and the second distribution plate include a plurality of orifices.

The number of the plurality of orifices of the first distribution plate is larger than the number of the plurality of orifices of the second distribution plate.

The number of the plurality of orifices of the second distribution plate is a half or less of the number of the plurality of orifices of the first distribution plate.

A gap of the plurality of orifices of the first distribution plate is smaller than a gap of the plurality of orifices of the second distribution plate.

A width of the plurality of orifices of the first distribution plate is smaller than a width of the plurality of orifices of the second distribution plate.

At least one of the first distribution plate, the second distribution plate, and the dispersion portion includes an aluminum material (Al).

Further including a supporting member on which a substrate is disposed within the chamber.

A gap between the supporting member and the first distribution plate is smaller than a gap between the first distribution plate and the dispersion portion.

A gap between the supporting member and the first distribution plate is smaller than at least one of a gap between the first distribution plate and the second distribution plate and a gap between the second distribution plate and the dispersion portion.

The supporting member is used as a positive electrode, and the first distribution plate is used as a negative electrode.

Further including a gas discharge port configured to supply the gas into the chamber, wherein an area of the dispersion portion is larger than a sectional area of the gas discharge port.

In another aspect, there is a method of depositing a thin film layer, the method including a first dispersing to disperse a gas injected into a chamber using a dispersion portion, a second dispersing to disperse the gas after the first dispersing using a second distribution plate, and a third dispersing to disperse the gas after the second dispersing using a first distribution plate.

The first dispersing disperses the gas is into a first area, and the second dispersing disperses the gas into a second area narrower than the first area.

The third dispersing disperses the gas into a third area narrower than the second area.

The third dispersing disperses the gas on a substrate disposed within the chamber to form the thin film layer thereon.

In another aspect, there is a method of manufacturing a solar cell including depositing a micro-crystalline silicon thin film layer using the method of depositing a thin film layer.

### BRIEF DESCRIPTION OF THE DRAWINGS

FIGS. 1 and 2 are views related to a solar cell according to an embodiment of the invention;

FIGS. 3 to 7 are views related to an apparatus and method for manufacturing a solar cell according to an embodiment of the invention;

FIGS. 8 to 13 are views related to comparing non-uniformity of thicknesses of solar cells of a Comparative Example and an embodiment of the invention;

FIGS. 14 and 15 are views illustrating an example of another manufacturing apparatus for lowering non-uniformity of a micro-crystalline silicon thin film layer according to an embodiment of the invention; and

FIGS. 16 to 19 are views illustrating structures of solar cells according to embodiments of the invention.

### DETAILED DESCRIPTION OF THE EMBODIMENTS

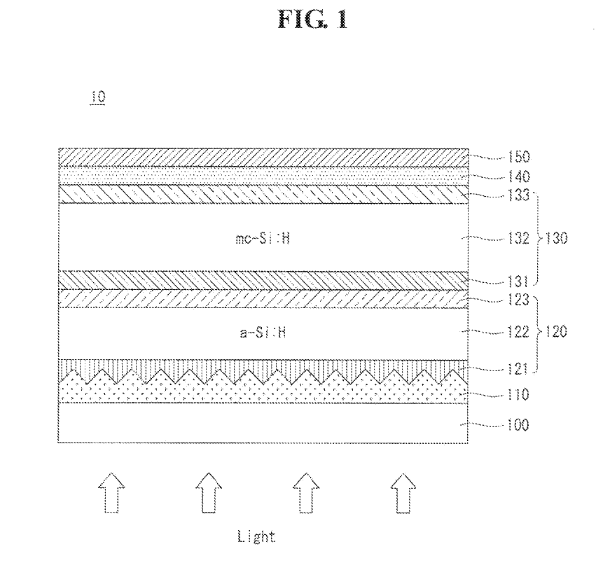

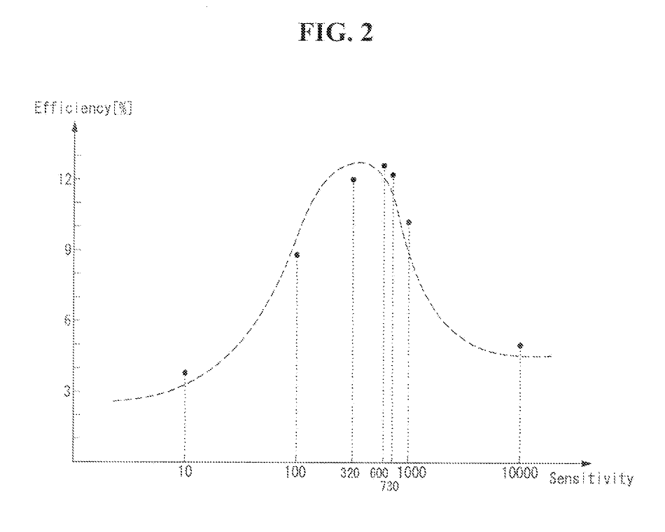

FIGS. 1 and 2 are views related to a solar cell according to an embodiment of the invention.

A solar cell 10 according to an embodiment of the invention comprises a micro-crystalline silicon layer. For example, as shown in FIG. 1, the solar cell 10 according to the implementation comprises a substrate 100, a first electrode 110 formed on the substrate 100, a first photoelectric conversion layer 120 and a second photoelectric conversion layer 130 formed on the first electrode 110, a reflective layer 140 formed on the second photoelectric conversion layer 130, and a second electrode 150.

Here, at least one of the first photoelectric conversion layer 120 and the second photoelectric conversion layer 130 comprises a micro-crystalline silicon layer. Preferably, the first photoelectric conversion layer 120 and the second photoelectric conversion layer 130 are sequentially disposed from a light incidence plane, and the second photoelectric conversion layer 130 comprises a micro-crystalline silicon layer.

Hereinafter, it is assumed that the first photoelectric conversion layer 120 is made of an amorphous silicon (a-Si) material and the second photoelectric conversion layer 130 is made of a micro-crystalline silicon (mc-Si) material.

The solar cell 10 according to an embodiment of the invention is not limited to a structure of FIG. 1 and may have any structure comprising a micro-crystalline silicon layer. For example, the solar cell 10 according to an embodiment of the invention may be formed in a double junction structure (pin-pin structure) of FIG. 1, a single junction structure (pin structure) made of a micro-crystalline silicon material, and a triple junction structure (pin-pin-pin structure). This is described in detail hereinafter.

Here, the first electrode 110 is a front electrode and the second electrode 150 is a rear electrode.

The substrate 100 provides space in which other functional layers may be disposed. Further, the substrate 100 may be made of a substantially transparent material, for example a glass or plastic material so that applied light more effectively arrive in the first and second photoelectric conversion layers 120 and 130.

In order to enhance transmittance of applied light, the first electrode 110 comprises a material having electrical conductivity while having substantial transparency. For example, the front electrode 110 may be made of a material selected from a group consisting of indium tin oxide (ITO), tin-based oxide (SnO₂), AgO, ZnO-(Ga₂O₃ or Al₂O₃), fluorine tin oxide (FTO), and mixtures thereof having high light transmittance and high electrical conductivity in order to pass through most light and to allow electricity to flow well.

The first electrode 110 is formed on a substantially entire surface of the substrate 100 and is electrically connected to the first photoelectric conversion layer 120. Accordingly, the first electrode 110 may collect the holes as carriers generated by applied light and output the holes.

Further, a plurality of unevenness having a random pyramid structure may be formed on an upper surface of the first electrode 110. That is, the first electrode 110 has a texturing surface. In this way, by texturing a surface of the first electrode 110, reflection of applied light may be reduced and an absorption rate of light may be enhanced and thus efficiency of the solar cell 10 may be improved.

FIG. 1 illustrates a case where unevenness is formed only on the first electrode 110, but unevenness may be formed on the first and second photoelectric conversion layers 120 and 130. Hereinafter, for convenience of description, a case where unevenness is formed only on the first electrode 110 is exemplified.

The second electrode 150 is made of a metal material having excellent electrical conductivity in order to enhance recovery efficiency of electric power generated by the first and second photoelectric conversion layers 120 and 130. Further, the second electrode 150 collects the electrons as carriers generated by applied light as electrically connected to the second photoelectric conversion layer 130 and outputs the electrons.

The reflective layer 140 again reflects light transmitting through the first and second photoelectric conversion layers 120 and 130 toward the first and second photoelectric conversion layers 120 and 130. Accordingly, the first and second photoelectric conversion layers 120 and 130 may increase generation of electric power using light reflected by the reflective layer 140. Accordingly, efficiency of the solar cell 10 may be improved.

The first and second photoelectric conversion layers 120 and 130 may convert light applied from the outside to electricity.

The first photoelectric conversion layer 120 comprises a first p-type semiconductor layer 121, a first i-type semiconductor layer 122, and a first n-type semiconductor layer 123. All of the first p-type semiconductor layer 121, the first i-type semiconductor layer 122, and the first n-type semiconductor layer 123 may be made of an amorphous silicon material.

The first p-type semiconductor layer 121 may be formed by using gas comprising impurities of a trivalent element such as boron, gallium, and indium in a raw material gas comprising silicon (Si).

The first i-type semiconductor layer 122 may reduce a recombination rate of a carrier and absorb light. The first i-type semiconductor layer 122 may generate a carrier such as an electron and a hole by absorbing applied light.

The first n-type semiconductor layer 123 may be formed by using gas comprising impurities of a pentavalent element such as phosphorus (P), arsenic (As), and antimony (Sb) in a raw material gas comprising silicon.

The second photoelectric conversion layer 130 may be a silicon cell using a micro-crystalline silicon material, for example hydrogenated micro-crystalline silicon (mc-Si:H).

The second photoelectric conversion layer 130 comprises a second p-type semiconductor layer 131, a second i-type semiconductor layer 132, and a second n-type semiconductor layer 133 sequentially formed.

Here, it is preferable that the second i-type semiconductor layer 132 of the second photoelectric conversion layer 130 is a micro-crystalline silicon layer comprising a micro-crystalline silicon material. Alternatively, all of the second p-type semiconductor layer 131, the second i-type semiconductor layer 132, and the second n-type semiconductor layer 133 of the second photoelectric conversion layer 130 may comprise a micro-crystalline silicon material.

In such a structure, when light is applied toward the first electrode 110, depletion is formed by the p-type semiconductor layers 121 and 131 and the n-type semiconductor layers 123 and 133 having a relatively high doping density within the i-type semiconductor layers 122 and 132, thereby forming an electric field. Electrons and holes generated in the i-type semiconductor layers 122 and 132, which are a light absorption layer by the photovoltaic effect are separated by a contact potential difference and move in different directions. For example, holes move toward the first electrode 110, and electrons move toward the second electrode 150. Electric power may be generated in this way.

Here, the first i-type semiconductor layer 122 may generate electrons and holes by mainly absorbing light of a short wavelength band. Further, the second i-type semiconductor layer 132 may generate electrons and holes by mainly absorbing light of a long wavelength band.

In this way, the solar cell 10 having a double junction structure of FIG. 1 generates carriers by absorbing light of a short wavelength band and a long wavelength band, thereby having high efficiency.

Non-uniformity in thicknesses of the first and second photoelectric conversion layers 120 and 130 should be fully lowered.

When non-uniformity in thicknesses of the first and second photoelectric conversion layers 120 and 130 is excessively large, generation of electric power may be distorted and thus efficiency of the solar cell may be deteriorated.

Further, because the second photoelectric conversion layer 130 comprises a micro-crystalline silicon material having an intermediate property of amorphous silicon and crystalline silicon, a thickness of the first photoelectric conversion layer 120 made of an amorphous silicon material may be thick.

Therefore, non-uniformity in thickness of the second photoelectric conversion layer 130 has a greater influence on the efficiency of the solar cell 10 than non-uniformity in thickness of the first photoelectric conversion layer 120. Accordingly, in order to improve non-uniformity in thickness of the solar cell 10, it is preferable to improve non-uniformity in thickness of the second photoelectric conversion layer 130.

Sensitivity of the second photoelectric conversion layer 130 may be adjusted to enhance efficiency of the solar cell 10. This is described with reference to FIG. 2 as follows.

FIG. 2 is a graph illustrating a relationship between efficiency of the solar cell 10 and sensitivity of the second photoelectric conversion layer 130. In FIG. 2, the horizontal axis is an axis of sensitivity and is represented with a log scale. Further, the vertical axis is an axis of efficiency of the solar cell 10 and indicates initial efficiency of the cell.

Further, sensitivity is (or a ratio expressed as) photo conductivity (PC)/dark conductivity (DC). Here, PC is conductivity of the second photoelectric conversion layer 130 when light is applied, and DC is conductivity of the second photoelectric conversion layer 130 when light is not applied. Therefore, sensitivity has no unit.

Referring to FIG. 2, when sensitivity of the second photoelectric conversion layer 130 is about 10, efficiency of the solar cell 10 is about 3.8%.

In such a case, when the number of defects is numerous in the second photoelectric conversion layer 130, even if light is applied from the outside, a small amount of electric power is generated and thus sensitivity is small.

However, when sensitivity of the second photoelectric conversion layer 130 is about 100, the solar cell 10 has efficiency of a high level of about 8.8%.

Further, when sensitivity of the second photoelectric conversion layer 130 is about 320, efficiency of the solar cell 10 is about 12.0%, when sensitivity of the second photoelectric conversion layer 130 is about 600, efficiency of the solar cell 10 is about 12.6%, and when sensitivity of the second photoelectric conversion layer 130 is about 730, efficiency of the solar cell 10 is about 12.2% and thus efficiency of the solar cell 10 is in a fully high level. In such a case, a defect of the second photoelectric conversion layer 130 is in a fully low level.

Further, when sensitivity of the second photoelectric conversion layer 130 is about 1,000, efficiency of the solar cell 10 is about 10.2% and somewhat reduced, but is in a still high level.

However, when sensitivity of the second photoelectric conversion layer 130 is about 10,000, efficiency of the solar cell 10 is about 5.0% and is in a very low level.

In this way, when sensitivity of the second photoelectric conversion layer 130 is about 10,000 or more, sensitivity of the second photoelectric conversion layer 130 is high and thus it looks as if electric power generation ability is excellent, but a property of the second photoelectric conversion layer 130 approaches that of amorphous silicon. Accordingly, the solar cell 10 may obtain the result comprising the first photoelectric conversion layer 120 of an amorphous silicon material and the second photoelectric conversion layer 130 approaching an amorphous silicon material. In this case, as a light absorption ability of the second photoelectric conversion layer 130 is deteriorated in the solar cell 10, efficiency of the solar cell 10 may be lowered.

In consideration of data of FIG. 2, sensitivity of the micro-crystalline silicon layer, i.e., the second photoelectric conversion layer 130 is preferably about 100 to 1,000, more preferably about 320 to 730, though not required.

An apparatus and method for manufacturing the solar cell 10 according to an embodiment of the invention are described as follow.

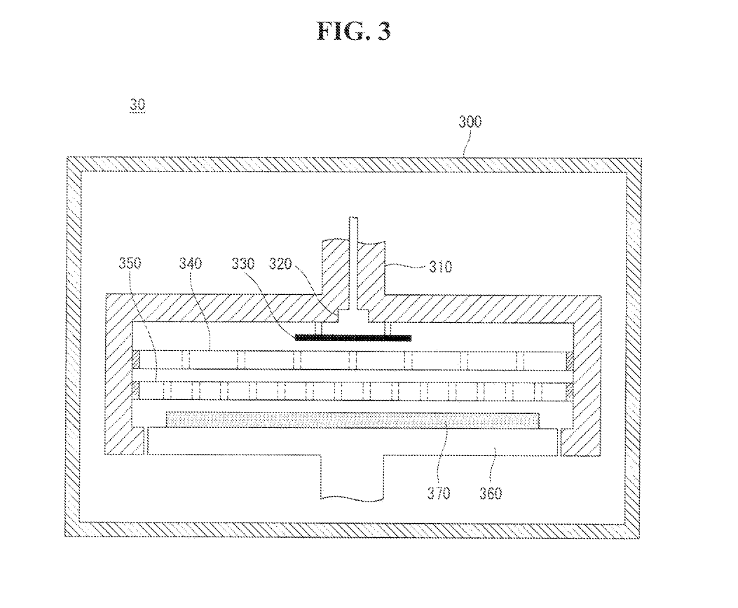

FIGS. 3 to 7 are views related to an apparatus and method for manufacturing a solar cell according to an embodiment of the invention. Hereinafter, only a case of manufacturing a micro-crystalline silicon thin film layer of the solar cell is described, but the manufacturing apparatus and the manufacturing method according to an embodiment of the invention may be applied to a case of forming a silicon thin film layer, for example, a case of manufacturing a silicon thin film layer of a liquid crystal display (LCD) or an amorphous silicon thin film layer.

First, referring to FIG. 3, a manufacturing apparatus 30 of the solar cell according to an embodiment of the invention comprises a chamber 310 at which a substrate 370 is disposed, a gas discharge port 320 for supplying gas into the chamber 310, a dispersion portion 330 for dispersing gas supplied from the gas discharge port 320, a second distribution plate 340 for distributing gas supplied from the dispersion portion 330, and a first distribution plate 350 for redistributing gas passing through the second distribution plate 340.

A supporting member 360 is disposed within the chamber 310, and the substrate 370 is disposed at the supporting member 360. Here, the supporting member 360 may support the substrate 370 and may apply heat to the substrate 370. Further, the supporting member 360 may be used as a positive electrode.

Further, the supporting member 360 may uniformly apply heat regardless of a position of the substrate 370.

A chamber outer wall 300 for enhancing a vacuum degree of the chamber 310 is disposed around the chamber 310.

Here, the manufacturing apparatus 30 of the solar cell of FIG. 3 may be a chamber. In this case, reference numeral 310 is referred to as an inner chamber and reference numeral 300 is referred to as an outer chamber. Hereinafter, for convenience of description, reference numeral 310 is referred to as a chamber and reference numeral 300 is referred to as an outer wall.

Here, the first distribution plate 350 is disposed apart a predetermined distance from the supporting member 360 and the substrate 370 within the chamber 310, and comprises a plurality of orifices. Here, the orifice is a predetermined penetration hole through which reaction gas may pass.

Hereinafter, orifices formed in the first distribution plate 350 are referred to as a first orifice. The first distribution plate 350 is used as a negative electrode.

The second distribution plate 340 comprises a plurality of orifices, as in the first distribution plate 350. Hereinafter, an orifice formed in the second distribution plate 340 is referred to as a second orifice.

The second distribution plate 340 is disposed in the chamber 310 between the gas discharge port 320 and the first distribution plate 350.

The second orifice 341 of the second distribution plate 340 is different from the first orifice 351 of the first distribution plate 350 in at least one of a gap, a width, or the number.

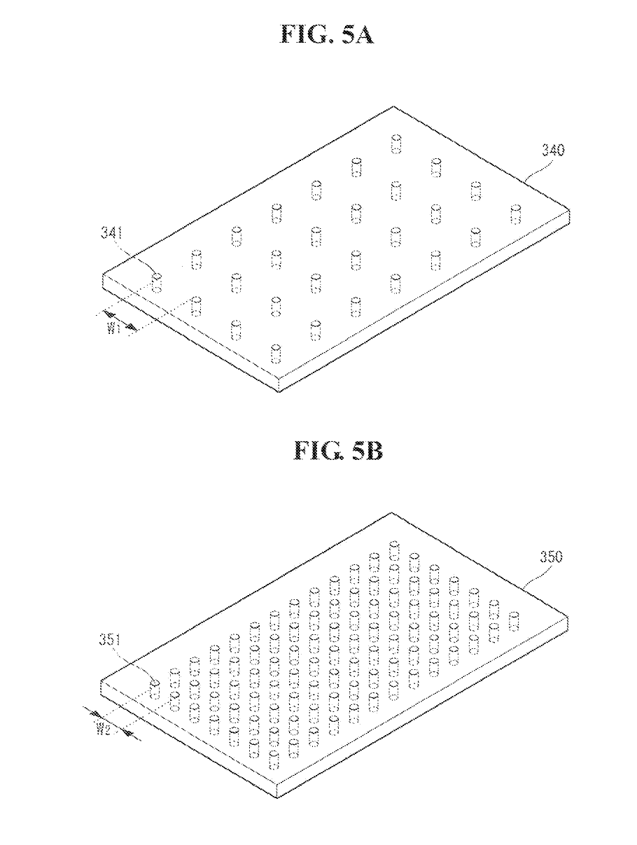

Specifically, the number of the second orifices 341 formed in the second distribution plate 340 shown in FIG. 5A is smaller than that of the first orifices 351 formed in the first distribution plate 350 shown in FIG. 5B.

Preferably, a gap W1 between two adjacent second orifices 341 in the second distribution plate 340 shown in FIG. 5A may be larger than a gap W2 between two adjacent first orifices 351 in the first distribution plate 350 shown in FIG. 5B.

Further, in order to enhance gas dispersion efficiency of the first and second distribution plates 350 and 340, it is preferable, though not required, that the number of the second orifices 341 formed in the second distribution plate 340 is a half or less of the number of the first orifices 351 formed in the first distribution plate 350.

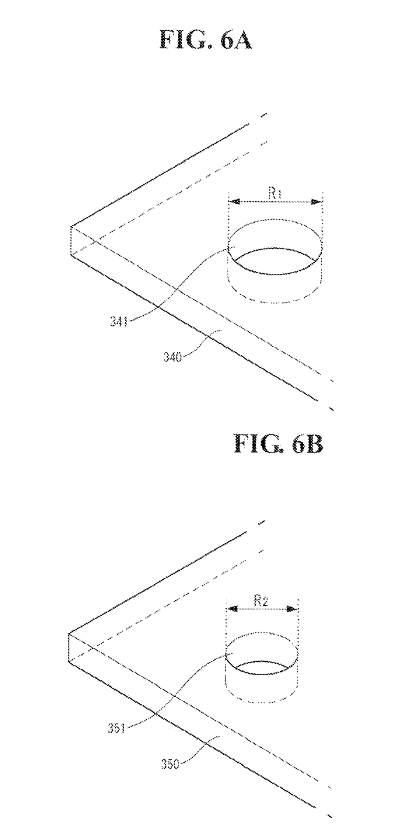

Alternatively, in order to enhance dispersion efficiency of gas, as shown in FIG. 6B, a width, i.e., a diameter R2 of the first orifice 351 having the relatively many number may be smaller than a diameter R1 of the second orifice 341, as shown in FIG. 6A.

The dispersion portion 330 may be disposed between the second distribution plate 340 and the gas discharge port 320.

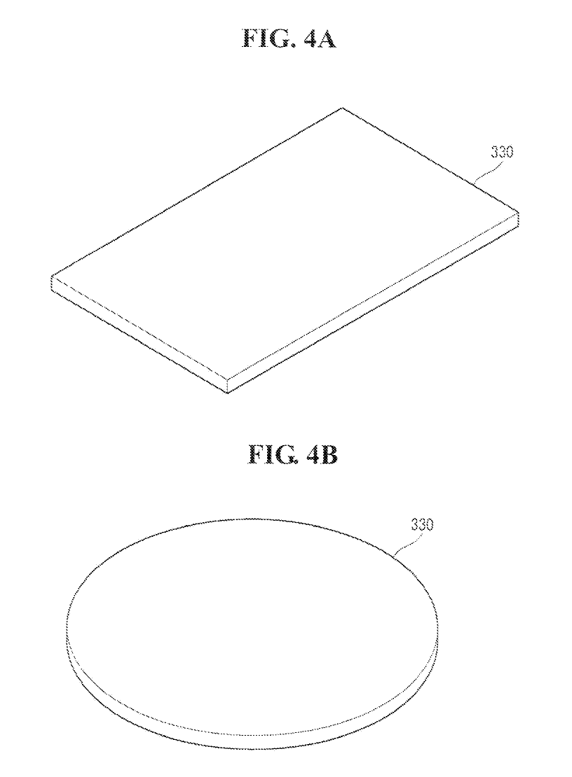

The dispersion portion 330 has a plate structure in which orifices are not formed, as shown in FIGS. 4A and 4B. For example, the dispersion portion 330 may have a disk form. Further, the dispersion portion 330 may have various shapes according to a shape of the substrate 370 disposed within the chamber 310. For example, the dispersion portion 330 may have a polygonal shape, as shown in FIG. 4A, or the dispersion portion 330 may have circular shape or an oval shape, as shown in FIG. 4B.

As shown in FIG. 7, when reaction gas is injected into the chamber 310 through the gas discharge port 320, gas injected into the dispersion portion 330 separated by a predetermined distance from the gas discharge port 320 may be primarily dispersed. Specifically, because the dispersion portion 330 is a plate in which an orifice is not formed, the injected gas may be dispersed by flowing around the dispersion portion 330.

Further, in order to improve gas dispersion efficiency by the dispersion portion 330, it is preferable, though not required, that an area of the dispersion portion 330 is larger than a sectional area of the gas discharge port 320.

In this way, at step of primarily dispersing gas using the dispersion portion 330, the injected gas may be dispersed into relatively wide space by flowing along the dispersion portion 330. Therefore, in such a step, gas injected into the chamber 310 may be dispersed into the relatively wide first area.

Thereafter, gas dispersed by the dispersion portion 330 may be again secondarily dispersed by the second distribution plate 340.

Specifically, gas dispersed by the dispersion portion 330 and arrived in the second distribution plate 340 may be more uniformly dispersed while passing through the second orifices 341 formed in the second distribution plate 340.

In this way, at step of secondarily dispersing gas using the second distribution plate 340, gas passes through the second orifice 341 formed in the second distribution plate 340, and gas may be dispersed into the second area relatively narrower than the first area, compared with a step in which the injected gas is dispersed by the dispersion portion 330.

Thereafter, gas secondarily dispersed by the second distribution plate 340 may be thirdly dispersed by the first distribution plate 350.

Specifically, gas dispersed by the second distribution plate 340 and arrived in the first distribution plate 350 may be more uniformly dispersed while passing through the first orifice 351 formed in the first distribution plate 350.

Here, the number of the first orifices 351 formed in the first distribution plate 350 is smaller than that of the second orifices 341 formed in the second distribution plate 340 and a gap W2 between the first orifices 351 is smaller than a gap W1 between the second orifices 341 and thus gas may be more uniformly dispersed.

In this way, at step of thirdly dispersing gas using the first distribution plate 350, gas passes through the first orifice 351 formed in the first distribution plate 350, and gas injected through the dispersion portion 330 is dispersed in a third area relatively narrower than the first area and the second area, compared with step dispersed by the second distribution plate 340.

Gas dispersed by the first distribution plate 350 may be emitted to the substrate 370.

In this case, when radio frequency (RF) electric power or very high frequency (VHF) electric power is applied between the first distribution plate 350, which is a negative electrode and the supporting member 360, which is a positive electrode, plasma discharge occurs between the first distribution plate 350 and the supporting member 360, and thus a thin film layer may be deposited on the substrate 370.

When such a method is used in a manufacturing process of the solar cell, a micro-crystalline silicon thin film layer may be deposited on the substrate 370.

Here, preferably, though not required, at least one of the first distribution plate 350, the second distribution plate 340, and the dispersion portion 330 comprises an aluminum material (Al) in order to suppress etching damage by plasma discharge. More preferably, though not required, all of the first distribution plate 350, the second distribution plate 340, and the dispersion portion 330 comprise an aluminum material (Al). Further, at least one of the first distribution plate 350 and the second distribution plate 340 may be formed integrally with the chamber 310. Further, at least one of the first distribution plate 350 and the second distribution plate 340 may be made of the same material as that of the chamber 310.

Further, in order to more effectively deposit a thin film layer, for example a micro-crystalline silicon thin film layer on the substrate 370 by plasma discharge generating between the first distribution plate 350 and the supporting member 360, a gap between the substrate 370 and the first distribution plate 350 should be fully small. For this, it is preferable, though not required, to fully reduce a gap t1 between the supporting member 360 and the first distribution plate 350. When a gap between the substrate 370 and the first distribution plate 350 is large, a deposition speed of the micro-crystalline silicon thin film layer becomes slow, and sensitivity characteristics of the micro-crystalline silicon thin film layer may be worsened.

In order to effectively deposit a thin film layer on the substrate 370, the gap t1 between the supporting member 360 and the first distribution plate 350 may be smaller than a gap t2 between the first distribution plate 350 and the dispersion portion 330. Preferably, though not required, the gap t1 between the supporting member 360 and the first distribution plate 350 may be smaller than at least one of a gap t4 between the first distribution plate 350 and the second distribution plate 340 and a gap t3 between the second distribution plate 340 and the dispersion portion 330.

As described above, when gradually dispersing gas injected into the chamber 310 using the dispersion portion 330, the second distribution plate 340, and the first distribution plate 350, the dispersed gas may be uniformly emitted to the substrate 370. Accordingly, a non-uniformity characteristic of a thickness of the micro-crystalline silicon thin film layer deposited on the substrate 370 may be improved. That is, a thickness of the micro-crystalline silicon thin film layer may be uniform.

Further, a sensitivity characteristic of the micro-crystalline silicon thin film layer deposited on the substrate 370 may be improved.

Further, in order to suppress deterioration of non-uniformity of the micro-crystalline silicon thin film layer formed on the substrate 370, it is preferable, though not required, to substantially equally sustain a gap between the first distribution plate 350 and the substrate 370 regardless of a position.

Further, in order to uniformly sustain sensitivity of the micro-crystalline silicon thin film layer formed on the substrate 370, it is preferable that the supporting member 360 uniformly emits heat regardless of a position of the substrate 370.

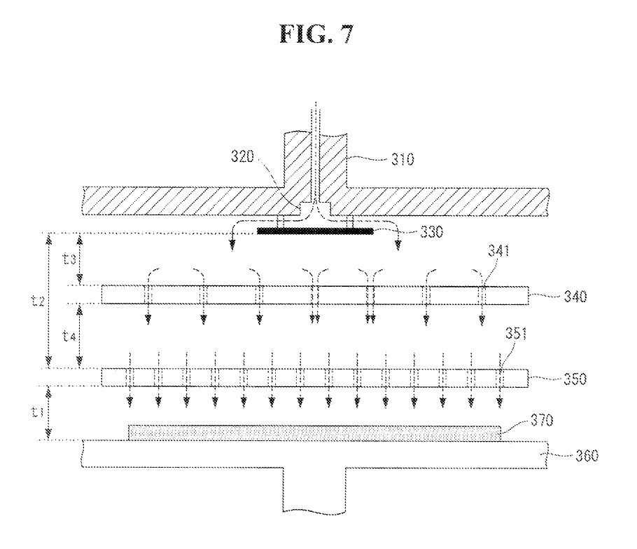

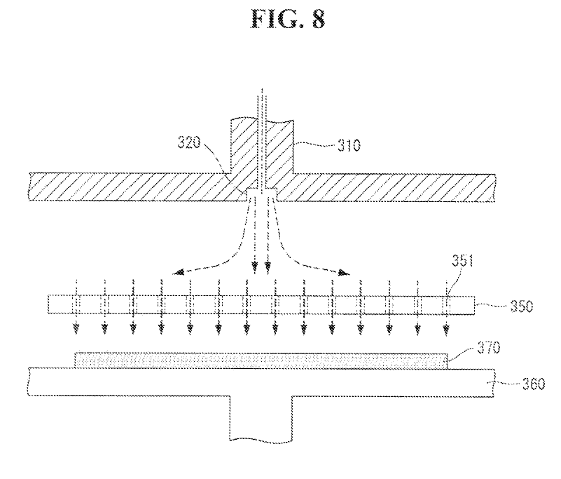

FIGS. 8 to 13 are views related to comparing non-uniformity of thicknesses of a solar cell of a Comparative Example and an embodiment of the invention.

In FIG. 8, the dispersion portion and the second distribution plate are omitted from the structure of FIG. 3, and an example of a manufacturing apparatus in which the first distribution plate 350 is disposed between the gas discharge port 320 and the substrate 370 is illustrated.

In a manufacturing apparatus having a configuration of FIG. 8, gas injected through the gas discharge port 320 directly arrives in the first distribution plate 350 and later arrived gas may be dispersed by passing through the first orifice 351 formed in the first distribution plate 350.

However, in such a configuration, because gas injected through the gas discharge port 320 directly arrives in the first distribution plate 350, a large amount of gas arrives in a central portion of the first distribution plate 350, and gas of a relatively smaller amount than that in the central portion arrives at the edge of the first distribution plate 350.

Accordingly, a large amount of gas may arrive in the central portion of the substrate 370, but gas of a relatively smaller amount than that of the central portion arrives in the edge portion of the substrate 370, and thus uniformity of a thickness of a micro-crystalline silicon thin film layer deposited on the substrate 370 may be deteriorated. Specifically, in the central portion of the substrate 370, a thin film layer of a relatively thick thickness may be deposited and in an edge portion of the substrate 370, a thin film layer of a relatively thin thickness may be deposited.

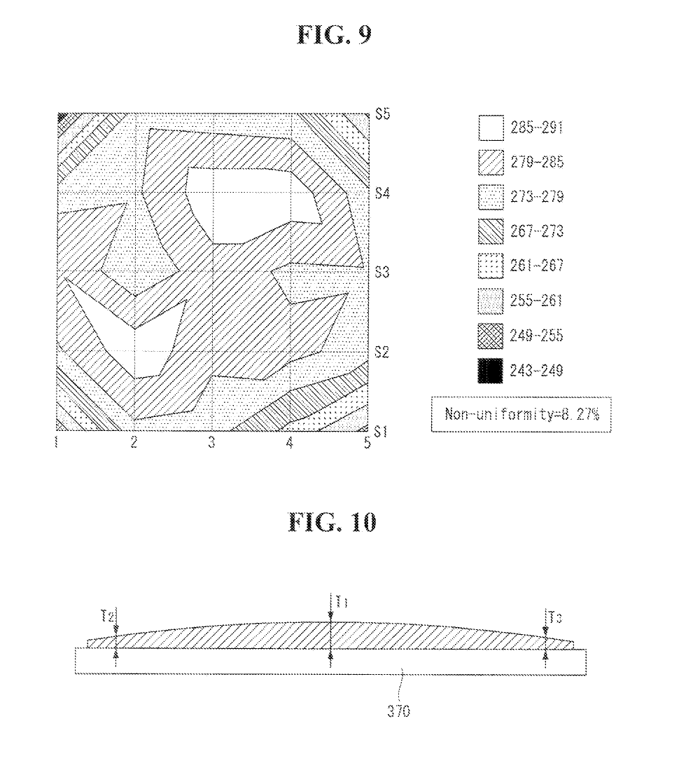

Measured data of uniformity in thickness of a solar cell manufactured using the manufacturing apparatus having a configuration of FIG. 8 are shown in FIG. 9.

In a manufacturing process condition of the solar cell, power is about 0.7 W/cm², a process pressure is about 4 torr, a depositing temperature is about 180° C., and SiH₄ and H₂ are used as gas.

As a measurement equipment of uniformity of a thin film layer, an elipsometer was used.

Further, non-uniformity of the thin film layer is calculated by Equation 1.

NU=(MAXT−MINT)×100/(MAXT−MINT) Equation 1

where NU is non-uniformity of a thin film layer, MAXT is a maximum thickness of a thin film layer, and MINT is a minimum thickness of a thin film layer.

As the measurement result, as shown in FIG. 9, non-uniformity of a micro-crystalline silicon thin film layer manufactured by the manufacturing apparatus of FIG. 8 is about 8.27%.

That is, the thin film layer manufactured by the manufacturing apparatus of FIG. 8 has a dome form in which a thickness T1 of the central portion is relatively larger than the thicknesses T2 and T3 of the edge portion, as shown in FIG. 10.

As described above, when a thin film layer is manufactured by the manufacturing apparatus of FIG. 8, non-uniformity of the manufactured thin film layer increases and thus a thickness characteristic may be deteriorated.

Further, in an edge portion of the substrate 370, because an amount and an inflow speed of arriving gas are less or slower than those of the central portion, sensitivity of a micro-crystalline silicon thin film layer deposited in the edge portion of the substrate 370 may be deteriorated. Accordingly, the thin film layer manufactured by the manufacturing apparatus of FIG. 8 may not have a sensitivity characteristic of FIG. 2.

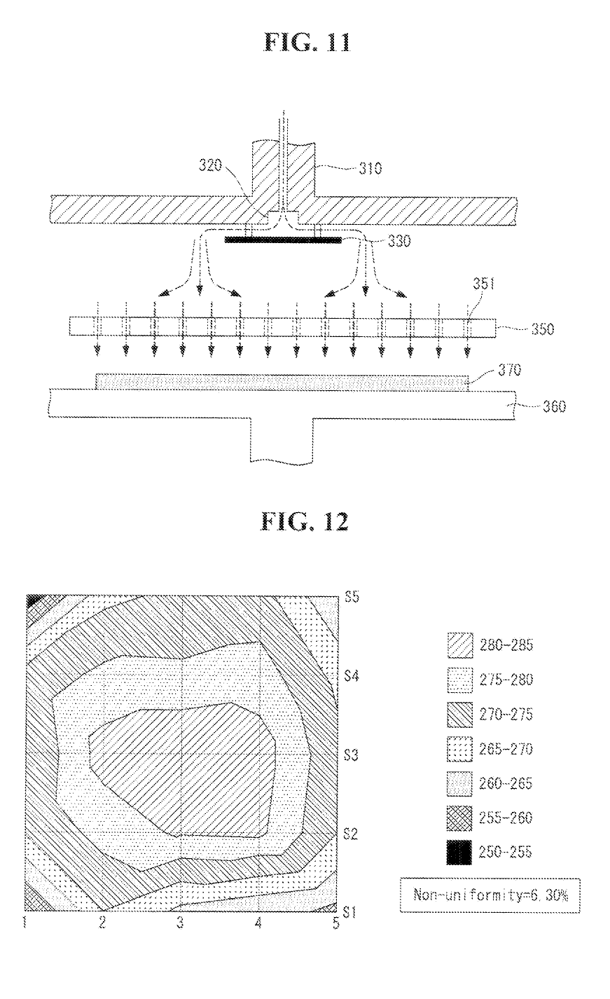

FIG. 11 illustrates an example of the manufacturing apparatus having a structure in which the second distribution plate is omitted from the structure of FIG. 3.

In the manufacturing apparatus having a configuration of FIG. 11, gas injected through the gas discharge port 320 is primarily dispersed by the dispersion portion 330, the dispersed gas arrives in the first distribution plate 350, and the arrived gas may be dispersed by passing through the first orifice formed in the first distribution plate 350.

However, in such a configuration, as shown in a case of FIG. 8, a dispersion effect of gas injected into the chamber 310 may not be fully obtained and thus a large amount of gas may arrive in a central portion of the substrate 370, however gas of a relatively smaller amount than that of the central portion of the substrate 370 may arrive in an edge portion of the substrate 370, and thus uniformity in thickness of the micro-crystalline silicon thin film layer deposited on the substrate 370 may be deteriorated.

Measured data of uniformity in thickness of the solar cell manufactured using the manufacturing apparatus having a configuration of FIG. 11 are shown in FIG. 12.

A manufacturing process condition of the solar cell is identical to that described above.

As the measured result of non-uniformity of the thin film layer, as shown in FIG. 12, non-uniformity of the micro-crystalline silicon thin film layer manufactured by the manufacturing apparatus of FIG. 11 is about 6.30%.

That is, the thin film layer manufactured by the manufacturing apparatus of FIG. 11 has a dome form in which a thickness of a central portion is relatively larger than that of the edge portion, as shown in FIG. 12.

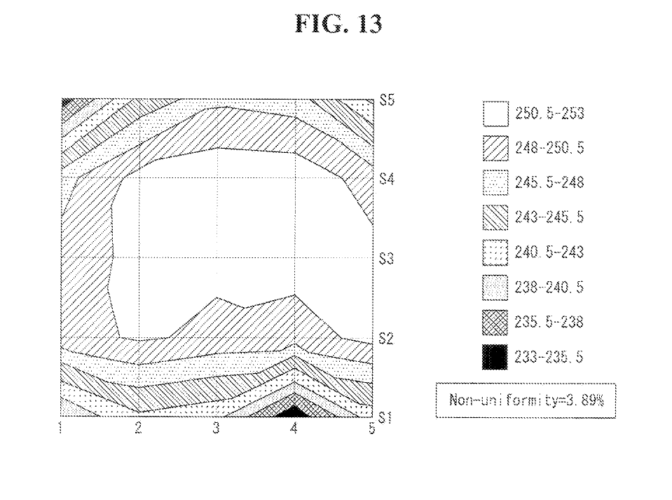

FIG. 13 illustrates measured data of uniformity in thickness of the solar cell manufactured using the manufacturing apparatus of FIG. 3.

The process condition is identical to that described above.

Referring to FIG. 13, non-uniformity of a micro-crystalline silicon thin film layer manufactured by the manufacturing apparatus of FIG. 3 is about 3.89%.

In consideration of a description of FIGS. 8 to 13, and as shown in FIG. 3, gradual distribution of gas injected into the chamber 310 using the dispersion portion 330, the second distribution plate 340, and the first distribution plate 350 is an effective method of improving non-uniformity of a micro-crystalline silicon thin film layer.

Further, when using the manufacturing apparatus shown in FIG. 3, control may be performed so that substantially identical amount of gas arrive in a central portion and an edge portion of the substrate 370, and an inflow speed of gas may be adjusted to an equivalent level. Accordingly, a sensitivity characteristic of a thin film layer deposited in the edge portion of the substrate 370 is substantially equal to that of a thin film layer deposited in the central portion of the substrate 370. Therefore, a micro-crystalline silicon thin film layer having a sensitivity characteristic shown in FIG. 2 may be obtained.

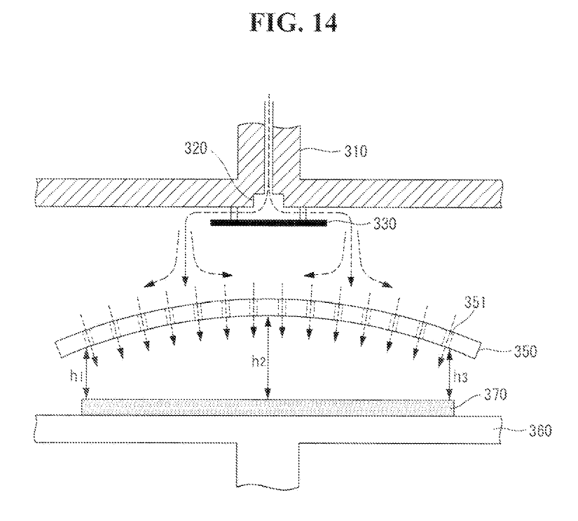

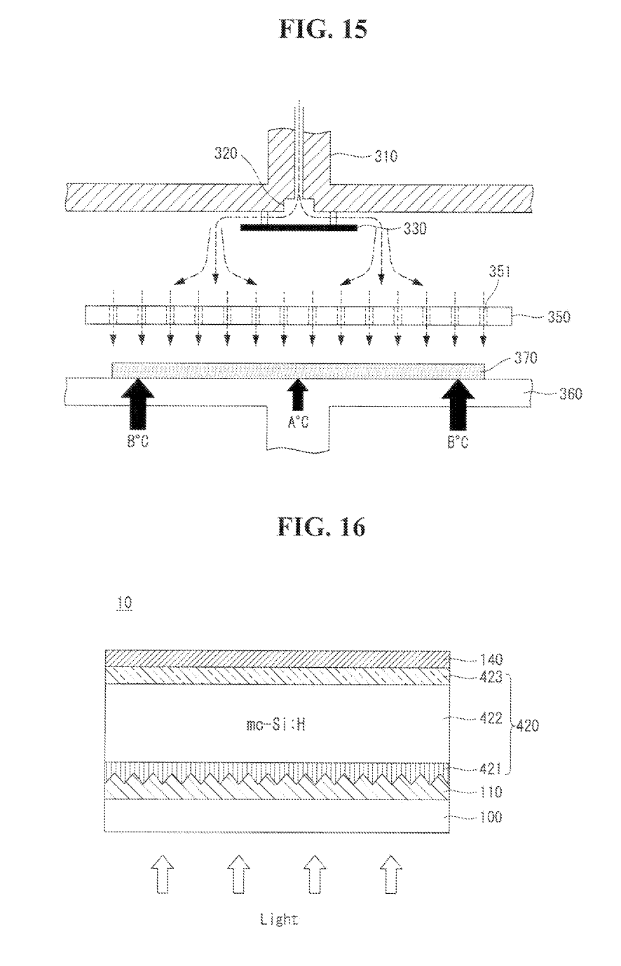

FIGS. 14 and 15 are views illustrating an example of another manufacturing apparatus for lowering non-uniformity of a micro-crystalline silicon thin film layer according to an embodiment of the invention.

FIG. 14 illustrates an example of manufacturing apparatus having a curvature in a first distribution plate 350 disposed between a gas discharge port 320 and a substrate 370.

In such a configuration, in a central portion of the substrate 370, a gap h2 between the substrate 370 and the first distribution plate 350 is relatively large, and in an edge portion thereof, gaps h1 and h3 between the substrate 370 and the first distribution plate 350 are relatively small.

Accordingly, in the central portion of the substrate 370, because enough space for diffusing gas passing through the first distribution plate 350 is provided, in the central portion of the substrate 370, by slowing down a depositing speed of a thin film layer, in the central portion and the edge portion of the substrate 370, depositing speeds of a thin film layer may be substantially equal.

Therefore, non-uniformity of the micro-crystalline silicon thin film layer formed on the substrate 370 may be fully lowered.

However, when using the manufacturing apparatus of FIG. 14, in the central portion of the substrate 370, a gap h2 between the substrate 370 and the first distribution plate 350 may excessively increase and thus a sensitivity characteristic of the micro-crystalline silicon thin film layer deposited in the central portion of the substrate 370 is deteriorated and thus it is difficult to obtain a sensitivity characteristic shown in FIG. 2.

FIG. 15 illustrates an example of a manufacturing apparatus using a method in which the supporting member 360 differentially applies heat to the substrate 370.

Specifically, the supporting member 360 applies relatively low heat A° C. to the central portion of the substrate 370 using a heater, and heat B° C. higher than A° C. may be applied to the edge portion of the substrate 370.

In such a case, because a temperature of the central portion of the substrate 370 is lower than that of the edge portion of the substrate 370, a depositing speed of a thin film layer in the central portion of the substrate 370 may be slower than that of a thin film layer in the edge portion thereof. Accordingly, non-uniformity in thickness of a thin film layer manufactured by the manufacturing apparatus of FIG. 15 may be lowered.

However, in the edge portion of the substrate 370 having a relatively high temperature, a crystallization degree of the deposited thin film layer is lowered, and in a central portion of the substrate 370 having a relatively low temperature, a crystallization degree of the deposited thin film layer is raised. Accordingly, the difference in sensitivity of a thin film layer formed in the central portion and the edge portion of the substrate 370 may be deepened, and it is difficult to obtain a sensitivity characteristic shown in FIG. 2.

Specifically, a crystallization degree of a micro-crystalline silicon thin film layer is one of variables determining sensitivity and when a crystallization degree is excessively high, the micro-crystalline silicon thin film layer has a property of amorphous silicon, and thus sensitivity of the micro-crystalline silicon thin film layer may be excessively raised.

Therefore, in a state where a temperature of the central portion of the substrate 370 is sustained, in a method of improving non-uniformity of the thin film layer as a method of rising a temperature of the edge portion of the substrate 370, sensitivity of the thin film layer formed in the edge portion of the substrate 370 is excessively raised, and thus it is difficult to obtain a sensitivity characteristic of FIG. 2.

Further, in a state where a temperature of the edge portion of the substrate 370 is sustained, in a method of improving non-uniformity of the thin film layer as a method of lowering a temperature of the central portion of the substrate 370, sensitivity of the thin film layer formed in the central portion of the substrate 370 may not satisfy a sensitivity characteristic of FIG. 2.

However, as shown in FIG. 3, when manufacturing a micro-crystalline silicon thin film layer using a method of sustaining a temperature of the substrate 370 in substantially an equivalent level regardless of a position while gradually dispersing gas injected into chamber 310 using the dispersion portion 330, the second distribution plate 340, and the first distribution plate 350 and of substantially uniformly sustaining a gap between the substrate 370 and the first distribution plate 350 regardless of a position of the substrate 370, non-uniformity of a thickness may be fully lowered and a sensitivity characteristic of the micro-crystalline silicon thin film layer may be sustained in a level of FIG. 2.

FIGS. 16 to 19 are views illustrating structures of solar cells according embodiments of the invention. Hereinafter, a description of portions described above in detail is omitted. For example, a micro-crystalline silicon layer of the solar cell of FIGS. 16 to 19 has substantially the same characteristic as that of the micro-crystalline silicon layer described above in detail.

Referring to FIG. 16, the solar cell 10 according to an embodiment of the invention comprises a photoelectric conversion layer 420 of a micro-crystalline silicon material. The solar cell 10 of FIG. 16 is a solar cell of a single junction structure (pin structure).

The photoelectric conversion layer 420 comprises a p-type semiconductor layer 421, an i-type semiconductor layer 422, and an n-type semiconductor layer 423. The i-type semiconductor layer 422 is preferably a micro-crystalline silicon layer comprising a micro-crystalline silicon material. Alternatively, all of a p-type semiconductor layer 431, an i-type semiconductor layer 432, and an n-type semiconductor layer 433 comprise a micro-crystalline silicon material.

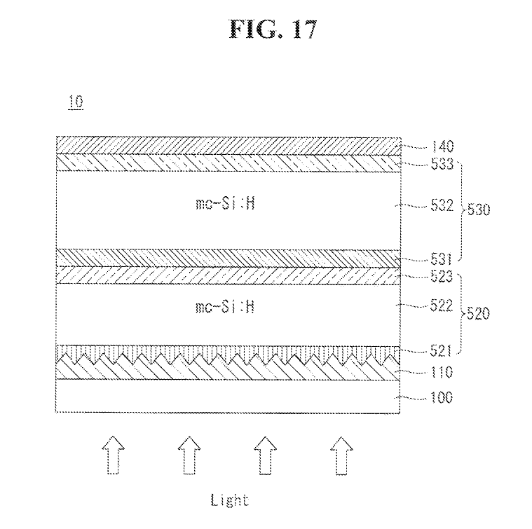

Alternatively, as shown in FIG. 17, the solar cell 10 having a double junction structure comprises a first photoelectric conversion layer 520 comprising a first i-type semiconductor layer 522 comprising a micro-crystalline silicon material and a second photoelectric conversion layer 530 comprising a second i-type semiconductor layer 532 comprising a micro-crystalline silicon material. That is, both the first i-type semiconductor layer 522 and the second i-type semiconductor layer 532 comprise a micro-crystalline silicon material.

In a structure of FIG. 17, all of the first p-type semiconductor layer 521, the first i-type semiconductor layer 522, and the first n-type semiconductor layer 523 comprise a micro-crystalline silicon material, or all of the second p-type semiconductor layer 531, the second i-type semiconductor layer 532, and the second n-type semiconductor layer 533 comprise a micro-crystalline silicon material.

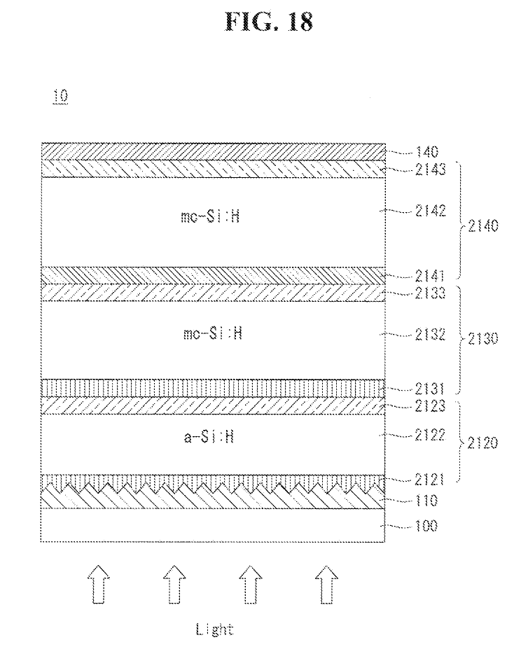

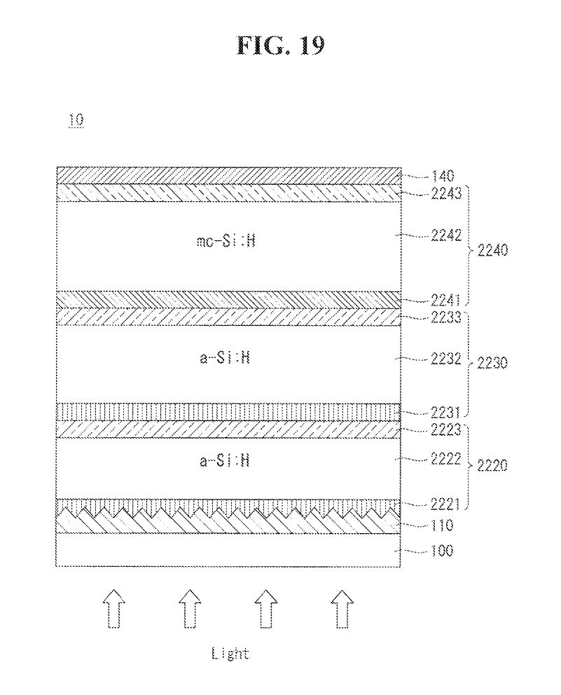

Referring to FIG. 18, the solar cell 10 according to an embodiment of the invention comprises a first photoelectric conversion layer 2120, a second photoelectric conversion layer 2130, and a third photoelectric conversion layer 2140. Such a solar cell may be a triple junction structure (pin-pin-pin structure) solar cell.

The first photoelectric conversion layer 2120 comprises a first p-type semiconductor layer 2121, a first i-type semiconductor layer 2122, and a first n-type semiconductor layer 2123.

The second photoelectric conversion layer 2130 comprises a second p-type semiconductor layer 2131, a second i-type semiconductor layer 2132, and a second n-type semiconductor layer 2133.

The third photoelectric conversion layer 2140 comprises a third p-type semiconductor layer 2141, a third i-type semiconductor layer 2142, and a third n-type semiconductor layer 2143.

The first photoelectric conversion layer 2120 may be an amorphous silicon cell using an amorphous silicon (a-Si) material, for example hydrogenated amorphous silicon (a-Si:H). The first i-type semiconductor layer 2122 of the first photoelectric conversion layer 2120 is made of a hydrogenated amorphous silicon (a-Si:H) material, and may generate electric power by absorbing light of a short wavelength band.

The second photoelectric conversion layer 2130 may be a micro-crystalline silicon cell using a micro-crystalline silicon (mc-Si) material, for example hydrogenated micro-crystalline silicon (mc-Si:H). The second i-type semiconductor layer 2132 of the second photoelectric conversion layer 2130 is made of a hydrogenated micro-crystalline silicon (mc-Si:H) material, and may generate electric power by absorbing light of an intermediate wavelength band between a short wavelength band and a long wavelength band.

The third photoelectric conversion layer 2140 may be a silicon cell using a micro-crystalline silicon (mc-Si) material, for example hydrogenated micro-crystalline silicon (mc-Si:H). The third i-type semiconductor layer 2142 of the third photoelectric conversion layer 2140 is made of a hydrogenated micro-crystalline silicon (mc-Si:H) material, and may generate electric power by absorbing light of a long wavelength band.

In this way, the solar cell 10 according to an embodiment of the invention comprises the first photoelectric conversion layer 2120, the second photoelectric conversion layer 2130, and the third photoelectric conversion layer 2140 gradually disposed from a light incidence plane, and the second photoelectric conversion layer 2130 and the third photoelectric conversion layer 2140 comprise a micro-crystalline silicon layer. That is, at least the second i-type semiconductor layer 2132 and the third i-type semiconductor layer 2142 are a micro-crystalline silicon layer.

Alternatively, as shown in FIG. 19, the solar cell 10 according to an embodiment of the invention comprises the first photoelectric conversion layer 2220, the second photoelectric conversion layer 2230, and the third photoelectric conversion layer 2240, and the third photoelectric conversion layer 2240 disposed at the farthest side from a light incidence plane may comprise a micro-crystalline silicon layer. That is, at least the third i-type semiconductor layer 2242 of the third photoelectric conversion layer 2240 may be a micro-crystalline silicon layer.

Although embodiments have been described with reference to a number of illustrative embodiments thereof, it should be understood that numerous other modifications and embodiments may be devised by those skilled in the art that will fall within the scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A solar cell, comprising:
a substrate;
a first electrode disposed on the substrate;
a second electrode; and
a photoelectric conversion layer disposed between the first electrode and the second electrode,
wherein the photoelectric conversion layer comprises a micro-crystalline silicon layer, and
sensitivity of the micro-crystalline silicon layer is about 100 to about 1,000, the sensitivity being a ratio expressed as photo conductivity (PC)/dark conductivity (DC).

2. The solar cell of claim 1, wherein the sensitivity of the micro-crystalline silicon layer is about 320 to about 730.

3. The solar cell of claim 1, wherein the photoelectric conversion layer comprises a p-type semiconductor layer, an n-type semiconductor layer, and an i-type semiconductor layer.

4. The solar cell of claim 3, wherein the i-type semiconductor layer is the micro-crystalline silicon layer.

5. The solar cell of claim 1, wherein the photoelectric conversion layer further comprises:
a first photoelectric conversion layer comprising a first p-type semiconductor layer, a first n-type semiconductor layer, and a first i-type semiconductor layer; and
a second photoelectric conversion layer comprising a second p-type semiconductor layer, a second n-type semiconductor layer, and a second i-type semiconductor layer.

6. The solar cell of claim 5, wherein the first photoelectric conversion layer and the second photoelectric conversion layer are sequentially disposed from a light incidence plane of the solar cell, and
the second i-type semiconductor layer is the micro-crystalline silicon layer.

7. The solar cell of claim 1, wherein the photoelectric conversion layer further comprises:
a first photoelectric conversion layer comprising a first p-type semiconductor layer, a first n-type semiconductor layer, and a first i-type semiconductor layer;
a second photoelectric conversion layer comprising a second p-type semiconductor layer, a second n-type semiconductor layer, and a second i-type semiconductor layer; and
a third photoelectric conversion layer comprising a third p-type semiconductor layer, a third n-type semiconductor layer, and a third i-type semiconductor layer.

8. The solar cell of claim 7, wherein the first photoelectric conversion layer, the second photoelectric conversion layer, and the third photoelectric conversion layer are sequentially disposed from a light incidence plane of the solar cell, and
the third i-type semiconductor layer is the micro-crystalline silicon layer.

9. A manufacturing apparatus of a solar cell, the manufacturing apparatus comprising:
a chamber;
a dispersion portion configured to disperse gas injected into the chamber;
a second distribution plate configured to distribute the gas supplied from the dispersion portion; and
a first distribution plate configured to redistribute the gas that passes through the second distribution plate.

10. The manufacturing apparatus of claim 9, wherein the dispersion portion has a plate shape.

11. The manufacturing apparatus of claim 9, wherein the first distribution plate and the second distribution plate comprise a plurality of orifices.

12. The manufacturing apparatus of claim 11, wherein the number of the plurality of orifices of the first distribution plate is larger than the number of the plurality of orifices of the second distribution plate.

13. The manufacturing apparatus of claim 12, wherein the number of the plurality of orifices of the second distribution plate is a half or less of the number of the plurality of orifices of the first distribution plate.

14. The manufacturing apparatus of claim 11, wherein a gap of the plurality of orifices of the first distribution plate is smaller than a gap of the plurality of orifices of the second distribution plate.

15. The manufacturing apparatus of claim 11, wherein a width of the plurality of orifices of the first distribution plate is smaller than a width of the plurality of orifices of the second distribution plate.

16. The manufacturing apparatus of claim 9, wherein at least one of the first distribution plate, the second distribution plate, and the dispersion portion comprises an aluminum material (Al).

17. The manufacturing apparatus of claim 9, further comprising a supporting member on which a substrate is disposed within the chamber.

18. The manufacturing apparatus of claim 17, wherein a gap between the supporting member and the first distribution plate is smaller than a gap between the first distribution plate and the dispersion portion.

19. The manufacturing apparatus of claim 17, wherein a gap between the supporting member and the first distribution plate is smaller than at least one of a gap between the first distribution plate and the second distribution plate and a gap between the second distribution plate and the dispersion portion.

20. The manufacturing apparatus of claim 17, wherein the supporting member is used as a positive electrode, and the first distribution plate is used as a negative electrode.

21. The manufacturing apparatus of claim 9, further comprising a gas discharge port configured to supply the gas into the chamber,
wherein an area of the dispersion portion is larger than a sectional area of the gas discharge port.

22. A method of depositing a thin film layer, the method comprising:
a first dispersing to disperse a gas injected into a chamber using a dispersion portion;
a second dispersing to disperse the gas after the first dispersing using a second distribution plate; and
a third dispersing configured to disperse the gas after the second dispersing using a first distribution plate.

23. The method of claim 22, wherein the first dispersing disperses the gas into a first area, and the second dispersing disperses the gas into a second area narrower than the first area.

24. The method of claim 23, wherein the third dispersing disperses the gas into a third area narrower than the second area.

25. The method of claim 22, wherein the third dispersing disperses the gas onto a substrate disposed within the chamber to form the thin film layer thereon.

26. A method of manufacturing a solar cell comprising depositing a micro-crystalline silicon thin film layer using the method of depositing a thin film layer according to any one of claims 22 to 25.
